(19) United States
(12) Patent Application Publication
(10) Pub. No.: US 2012/0049257 A1
(43) Pub. Date: Mar. 1, 2012

(54) SEMICONDUCTOR DEVICE

(75) Inventors: SungHo Lee, Hwaseong-si (KR); Jin Choi, Yongin-si (KR); Yong-Ho Yoo, Yongin-si (KR); Jong-Hyuk Kang, Gangnam-gu (KR); Hyun-Joo Cha, Seoul (KR); Tae-Jung Park, Busan (KR)

(73) Assignee: Samsung Electronics Co., Ltd.

(21) Appl. No.: 13/208,997

(22) Filed: Aug. 12, 2011

(30) Foreign Application Priority Data
Aug. 25, 2010 (KR) 10-2010-0082585

(51) Int. Cl. H01L 27/108; H01L 29/92

(52) U.S. Cl. 257/296; 257/532; 257/E27.084; 257/E29.342

(57) ABSTRACT

A DRAM device can include a plurality of capacitors that are arranged in a line in a first direction. Each of the capacitors can include an upper electrode. A contact pattern having a line shape can extend in the first direction and can be electrically connected to each of the upper electrodes. A conductor can be on the contact pattern opposite the upper electrodes and can be electrically connected to the contact pattern.

### CROSS-REFERENCE TO RELATED APPLICATIONS

This U.S. non-provisional patent application claims priority under 35 U.S.C. §119 of Korean Patent Application No. 10-2010-0082585, filed on Aug. 25, 2010, the entire contents of which are hereby incorporated by reference.

### BACKGROUND

The present inventive concept herein relates to semiconductor devices and methods of manufacturing the same, and more particularly, to a semiconductor device including a capacitor and a method of manufacturing the same.

As the level of integration of semiconductor devices increases, the electrical resistance of associated components in the device can increase. For instance, as the size of the device decreases, the area utilized to connect an upper electrode of a capacitor to a metal wire may be reduced, which can increase the electrical resistance of the contact with the upper electrode of the capacitor, thereby possibly reducing reliability.

### SUMMARY

Embodiments of the inventive concept provide a semiconductor device. Pursuant to these embodiments, a DRAM device can include a plurality of capacitors that are arranged in a line in a first direction. Each of the capacitors can include an upper electrode. A contact pattern having a line shape can extend in the first direction and can be electrically connected to each of the upper electrodes. A conductor can be on the contact pattern opposite the upper electrodes and can be electrically connected to the contact pattern.

In some embodiments according to the inventive concept, the contact pattern can be a unitary structure that bridges at least two of the upper electrodes in the first direction. In some embodiments according to the inventive concept, a width of the contact pattern can become progressively less toward the upper electrodes. In some embodiments according to the inventive concept, the device can further include a plurality of transistors on a substrate, where each of the transistors can include conductive patterns that extend in a second direction that is perpendicular to the first direction, and first and second impurity regions that are on opposing sides of each of the conductive patterns. Bit lines can be electrically connected to the first impurity regions and can extend in the first direction.

In some embodiments according to the inventive concept, the upper electrodes can each include flat upper surfaces that face the contact pattern, where the flat upper surfaces each having respective heights that are about equal to one another.

In some embodiments according to the inventive concept, a semiconductor device can include a plurality of capacitors that each include a lower electrode, an upper electrode on the lower electrode, and a dielectric layer that is between the upper and lower electrodes. A contact pattern can have a line shape that extends in a direction, and is electrically connected to the upper electrodes. A wire can be electrically connected to the contact pattern.

In some embodiments according to the inventive concept, a semiconductor device can include a substrate that includes an active region having a major axis in a first direction. A plurality of transistors can be on the substrate, where each includes conductive patterns extending in a second direction that is perpendicular to the first direction, and first and second impurity regions located on opposing sides of each of the conductive patterns. Bit lines can be electrically connected to the first impurity regions and can extend in the first direction. A plurality of capacitors can be electrically connected to respective ones of the second impurity regions. A contact pattern can have a line shape and can be electrically connected to the plurality of capacitors and extend in the first direction. A wire can be electrically connected to the contact pattern and can extend in the first direction.

In some embodiments according to the inventive concept, a method of manufacturing a semiconductor device can be provided by forming a plurality of lower electrodes that are spaced apart from one another in a first direction on a substrate. A dielectric layer can be formed on the lower electrodes and a plurality of upper electrodes can be formed to fill spaces between the lower electrodes on which the dielectric layer is formed. An upper portion of the upper electrode can be etched to form a recess that extends in the first direction. The recess can be filled to form a contact pattern that protrudes from an upper surface of the upper electrode. A wire can be formed to electrically connect to the contact pattern.

### BRIEF DESCRIPTION OF THE DRAWINGS

FIG. 1 is a cross sectional view for illustrating semiconductor devices in accordance with embodiments of the inventive concept.

FIGS. 2A through 2I are cross sectional views illustrating methods of manufacturing semiconductor devices illustrated in FIG. 1.

FIGS. 3A through 3I are plan views illustrating methods of manufacturing the semiconductor device illustrated in FIG. 1.

FIGS. 4A and 4B are schematic views illustrating differences in electrical resistance between a cylindrical shape contact pattern and a line shape contact pattern in accordance with embodiments of the inventive concept.

FIG. 5A is a block diagram illustrating a system including a memory device in accordance with embodiments of the inventive concept.

FIG. 5B is a block diagram illustrating a memory card to which a memory device in accordance with embodiments of the inventive concept can be applied.

### DESCRIPTION OF EMBODIMENTS ACCORDING TO THE INVENTIVE CONCEPT

Preferred embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present.

Embodiments of the inventive concept may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

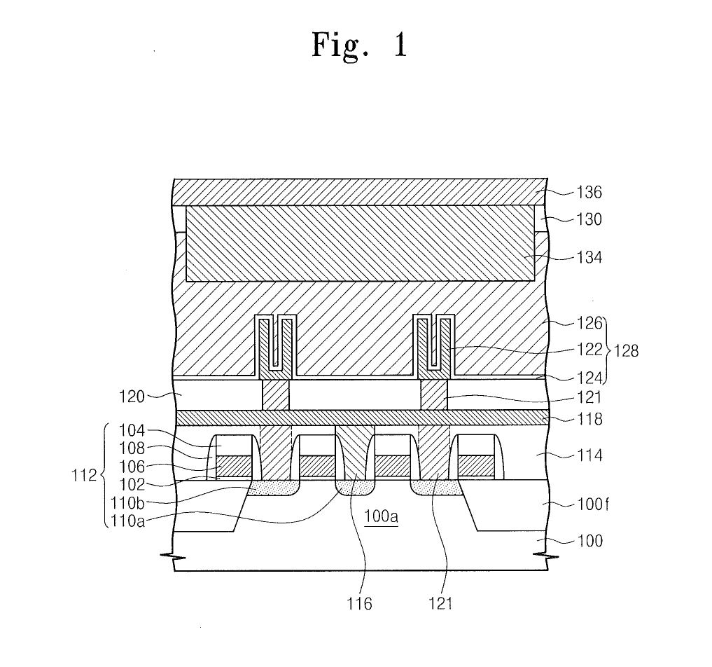

FIG. 1 is a cross sectional view for illustrating a semiconductor device in accordance with an embodiment of the inventive concept.

Referring to FIG. 1, a semiconductor device may include a substrate 100, transistors 112, first contact patterns 116, second contact patterns 121, bit lines 118, capacitors 128, third contact pattern 134 and a wire 136.

The substrate 100 may be a semiconductor substrate including silicon, germanium and silicon/germanium, a silicon on insulator (SOI) substrate or a germanium on insulator (GOI) substrate.

The substrate 100 may include an active region 100a and a field region 100f. The field region 100f is formed of oxide, nitride or oxynitride and may define the active region 100a in the substrate 100. For example, the active region 100a may have an oval shape having a major axis direction along a first direction.

Each of the transistors 112 may include a gate insulating layer 102, a first conductive pattern 106, a first impurity region 110a and a second impurity region 110b.

The gate insulating layer 102 may be formed between the substrate 100 and the first conductive pattern 106 to insulate the first conductive pattern 106 from the substrate 100.

The first conductive pattern 106 may extend in a second direction. The second direction is different from the first direction. For example, the second direction may be perpendicular to the first direction. The first conductive pattern 106 may cross the active region 100a. Elements of the first conductive patterns 106 may be spaced apart from one another at regular intervals and may be parallel to one another. The elements of the first conductive patterns 106 extending in the second direction may function as word lines.

The first impurity region 110a and the second impurity region 110b may be formed in the substrate 100 on both sides of the first conductive pattern 106. The first and second impurity regions 110a and 110b may function as a source/drain region.

Each of the transistors 112 may further include a mask 104 disposed on the first conductive pattern 106 and a spacer 108 disposed on a sidewall of the first conductive pattern 106.

The semiconductor device may further include a first insulating layer 114 filling the transistors 112. The first insulating layer 114 may include oxide, nitride or oxynitride.

The first contact patterns 116 may penetrate the first insulating layer 114 to be electrically connected to the first impurity regions 110a respectively. Each of the first contact patterns 116 may have a pillar shape. For example, the first contact pattern 116 may have a cylindrical shape or a polyprism shape.

The bit lines 118 may be electrically connected to the first contact patterns 116. A plurality of the first contact patterns 116 may be electrically connected to single bit line 118, and may be arranged in an extension direction the bit line 118.

The bit lines 118 may be arranged to extend in the first direction on the first insulating layer 114. The bit lines 118 may be spaced from one another at equal intervals and may be parallel to one another.

The semiconductor device may further include a second insulating layer 120 filling the bit lines 118. The second insulating layer 120 may include oxide, nitride and oxynitride.

The second contact patterns 121 may penetrate the second insulating layer 120 and the first insulating layer 114 to be electrically connected to the second impurity regions 110b respectively. Each of the second contact patterns 121 may have a pillar shape. For example, the second contact pattern 121 may have a cylindrical shape or a polyprism shape.

The capacitors 128 may include lower electrodes 122, a dielectric layer 124 and an upper electrode 126.

In embodiments of the inventive concept, the semiconductor device may be a memory cell and a unit cell of the memory cell may have a 6F² structure. In the memory cell structure of 6F², a unit cell is based on one lower electrode 122. A unit cell is 6F² because the dimensions of the unit cell can be expressed as 3F×2F based on the contact pattern connected to the lower electrode 122.

The dielectric layer 124 may continuously formed on the lower electrodes 122 along a profile of the lower electrodes 122 and the upper electrode 126 may be disposed on the dielectric layer 124 while filling the lower electrodes 122.

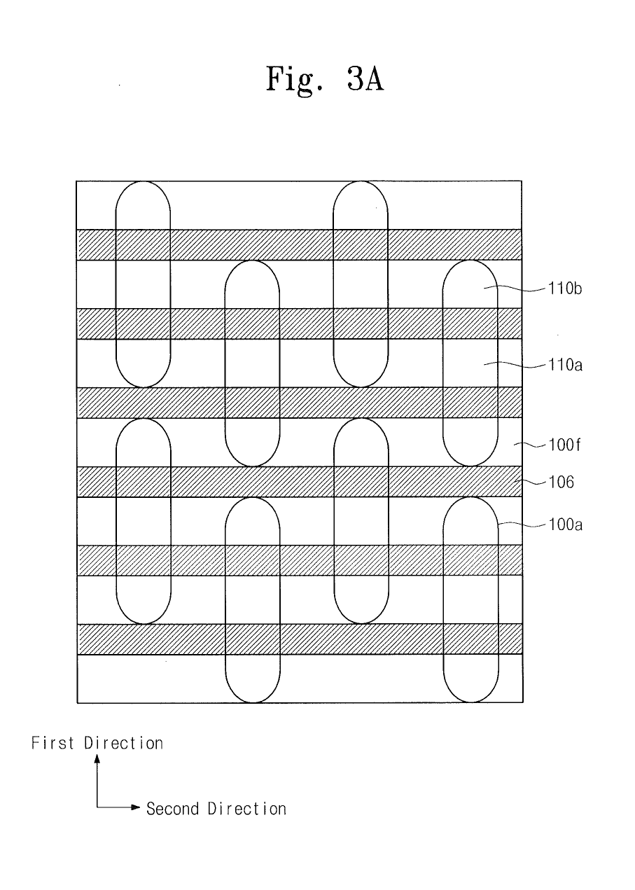

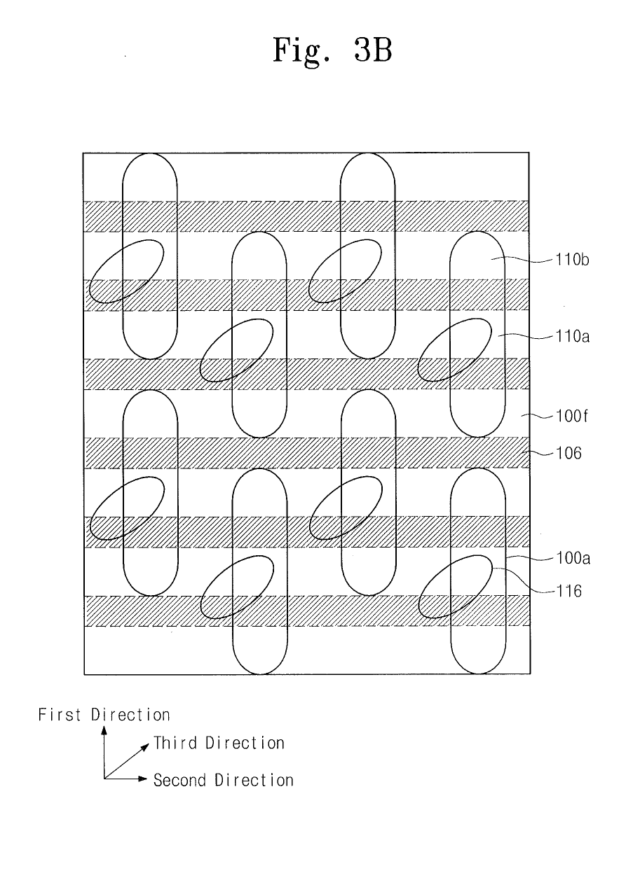

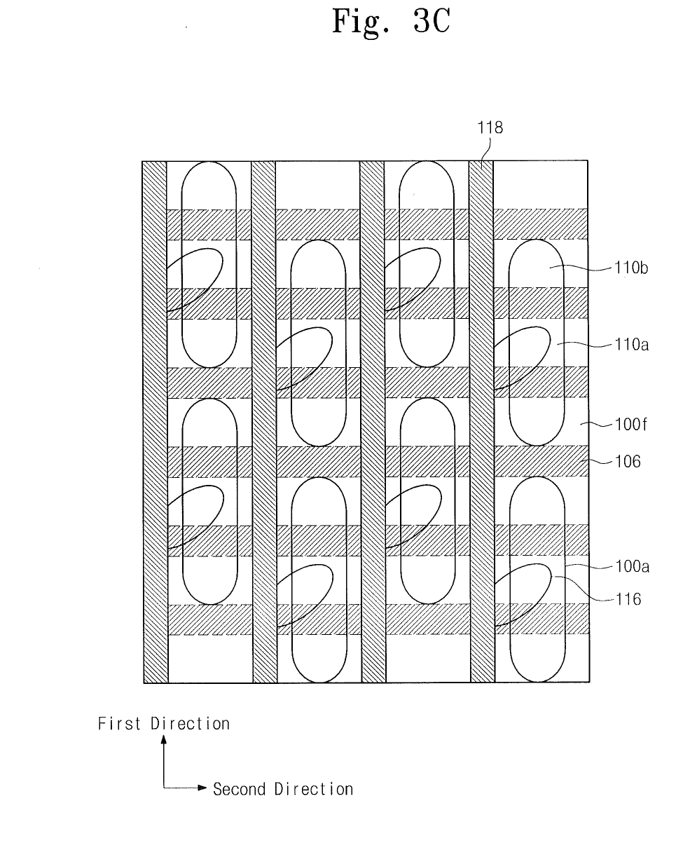

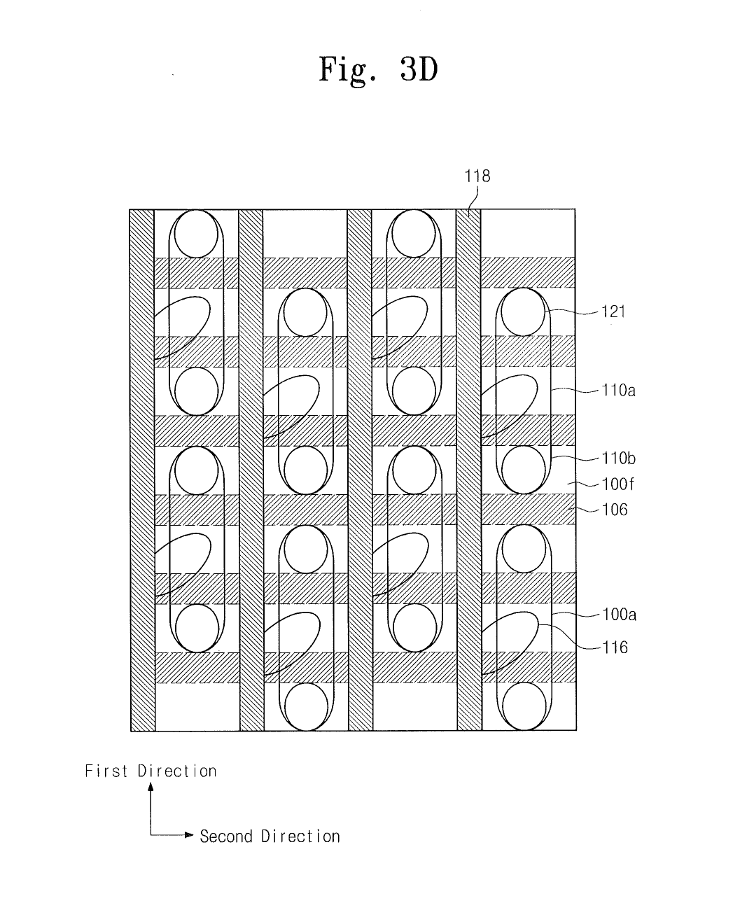

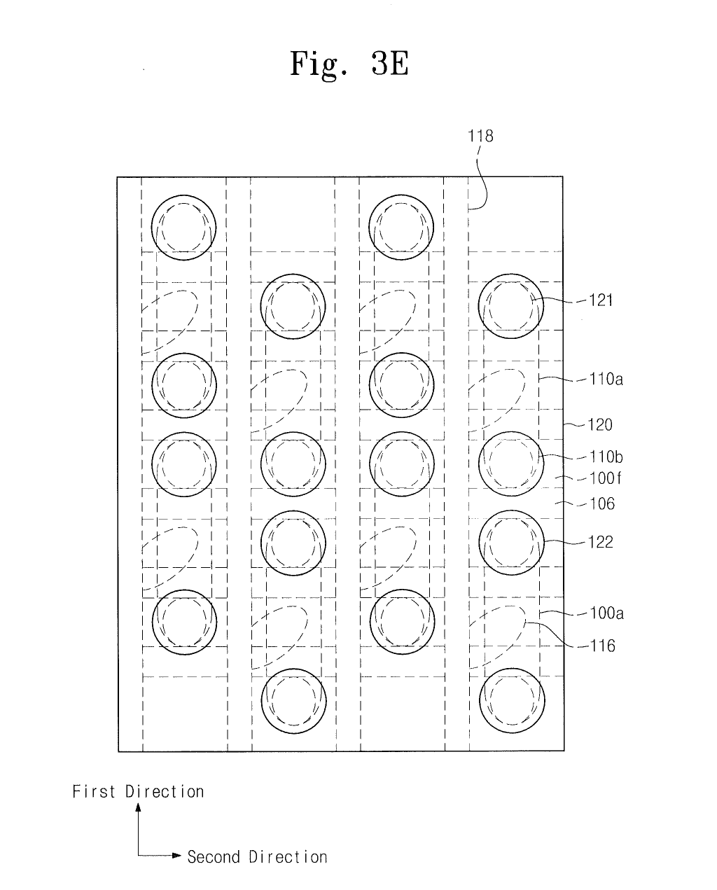

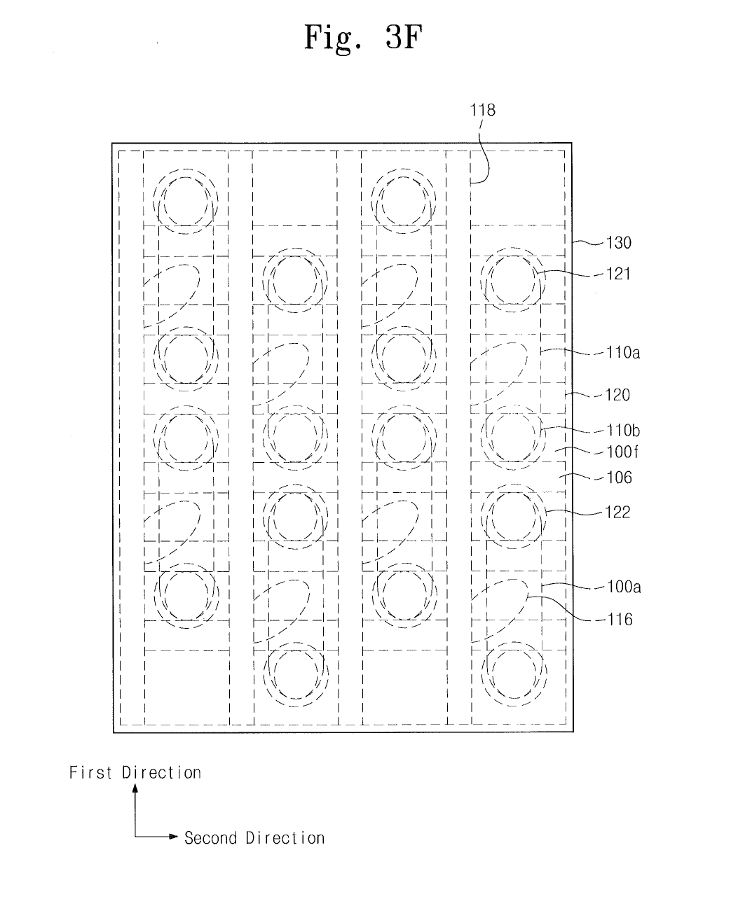

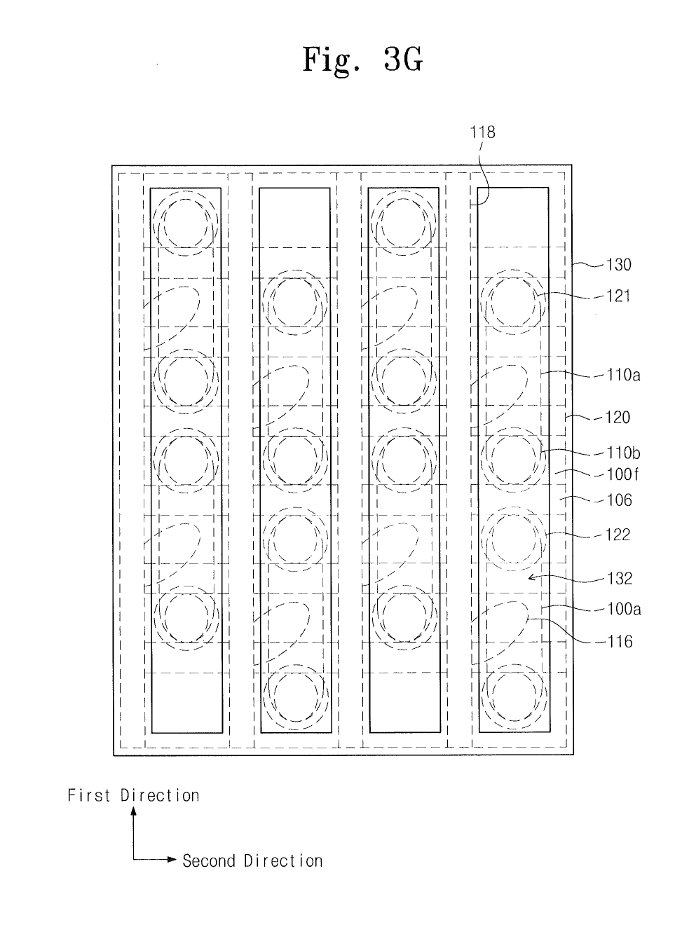

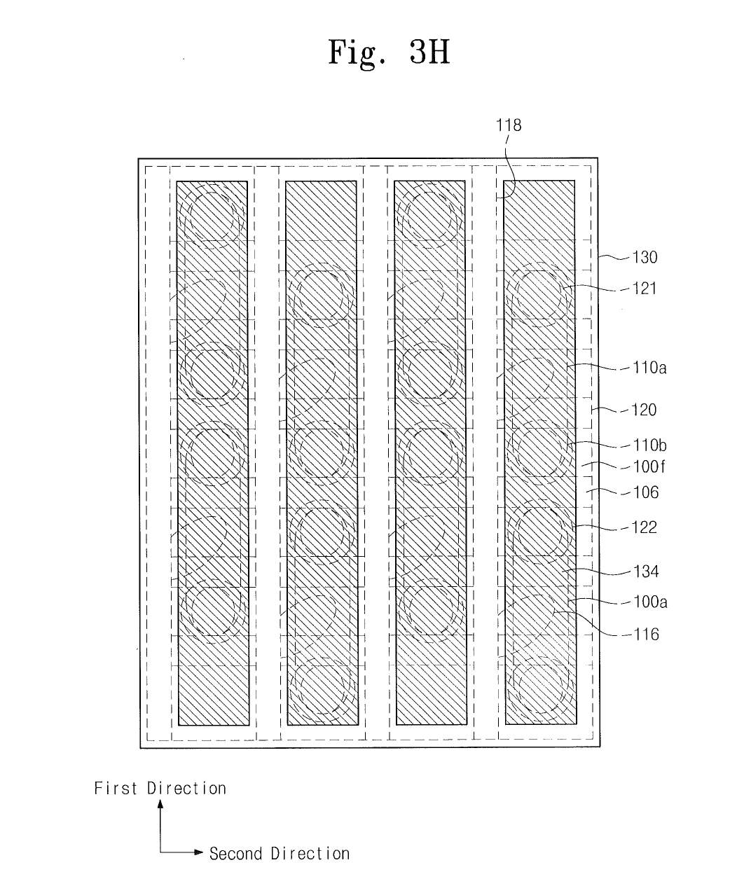

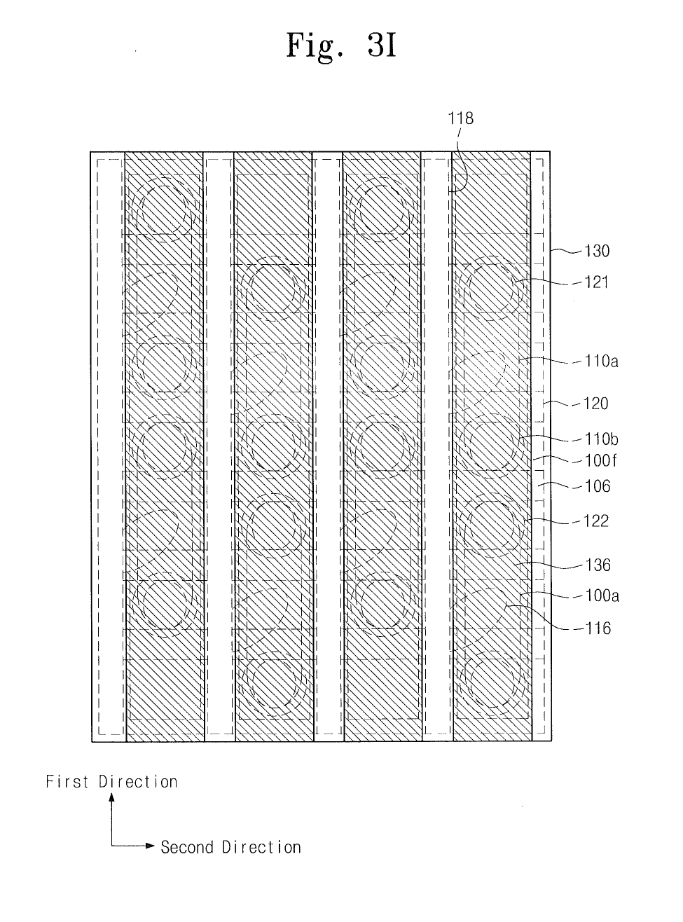

The lower electrodes 122 may be electrically connected to the second contact patterns 121 respectively. Each of the lower electrodes 122 may have a hollow cylindrical shape a bottom surface of which is closed. Each of the lower electrodes 122 may also include polysilicon doped with an impurity. The lower electrodes 122 may be arranged to be spaced apart from one another in the first direction and the second direction. When assuming that the first direction is a column direction, the second direction may be a row direction. According to embodiments of the inventive concept, as illustrated in FIG. 3E, for a space efficiency, the lower electrodes 122 may be disposed in a zigzag pattern along the row direction.

In the case that the lower electrode 122 has a hollow cylindrical shape, the dielectric layer 124 may be formed not to completely fill the inside of the lower electrode 122. The dielectric layer 124 may also have a single layer structure or a multilayer structure. For example, when the dielectric layer 124 has a multilayer structure, the multilayer structure may be a structure that an oxide layer, a nitride layer and an oxide layer are sequentially stacked.

The upper electrode 126 may be disposed while filling the lower electrodes on which the dielectric layer 124 is formed. The upper electrode 126 may have a flat upper surface and may have an upper surface that is the same level overall. The upper electrode 126 may have a top surface of first area.

The semiconductor device may further include a third insulating layer 130 disposed on the upper electrode 126. The third insulating layer 130 may include oxide, nitride and oxynitride.

The third contact pattern 134 may penetrate the third insulating layer 130 to be electrically connected to the upper electrode 126. According to embodiments of the inventive concept, the third contact pattern 134 may have a line shape and extend in the column direction among the arrangement directions of the lower electrodes 122. That is, the third contact pattern 134 may extend in the first direction.

An area of the third contact pattern 134 may gradually become small as the third contact pattern 134 approaches the bottom. A vertical cross section of the third contact pattern 134 may have a trapezoid shape having a wider upper portion than a lower portion.

Since the third contact pattern 134 electrically connected to the upper electrode 126 has a line shape, an area of the third contact pattern 134 that is in contact with the upper electrode 126 increases and thereby an electrical resistance of the third contact pattern 134 may be reduced

The wire 136 may be disposed to be electrically connected to the third contact pattern 134. The wire 136 may extend in the same direction as the third contact pattern 134. That is, the wire 136 may extend in the first direction.

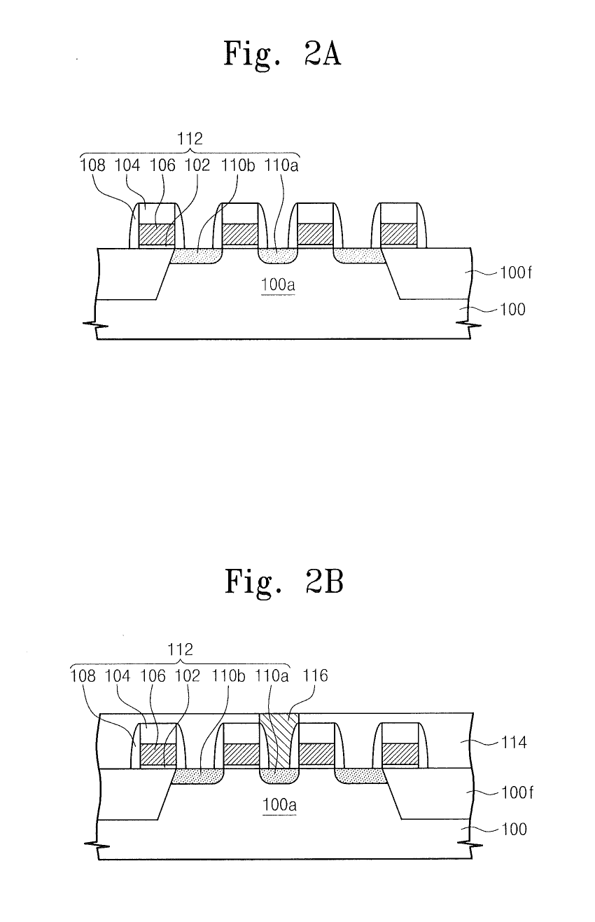

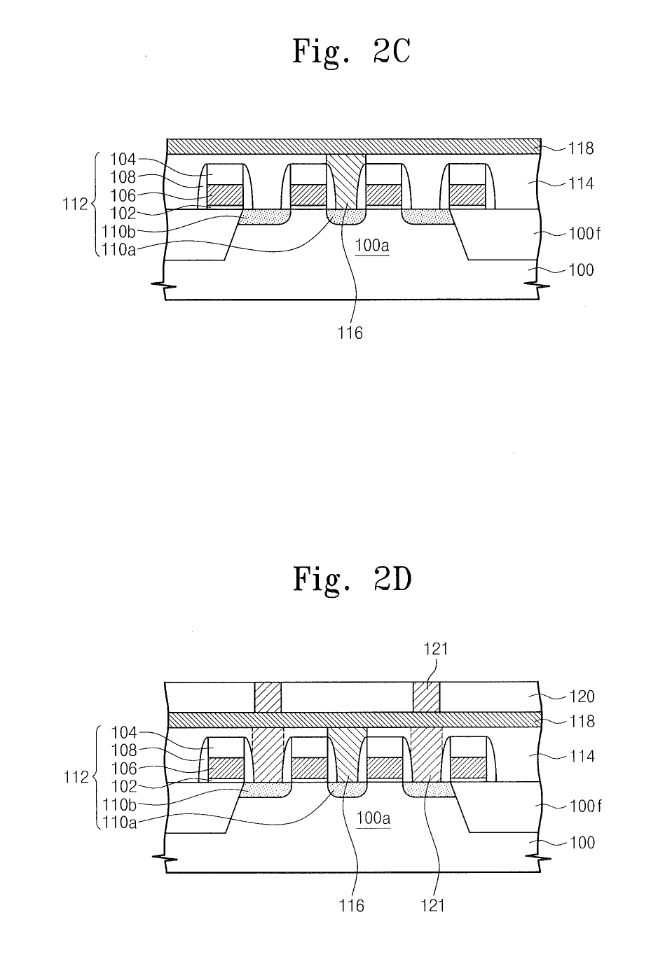

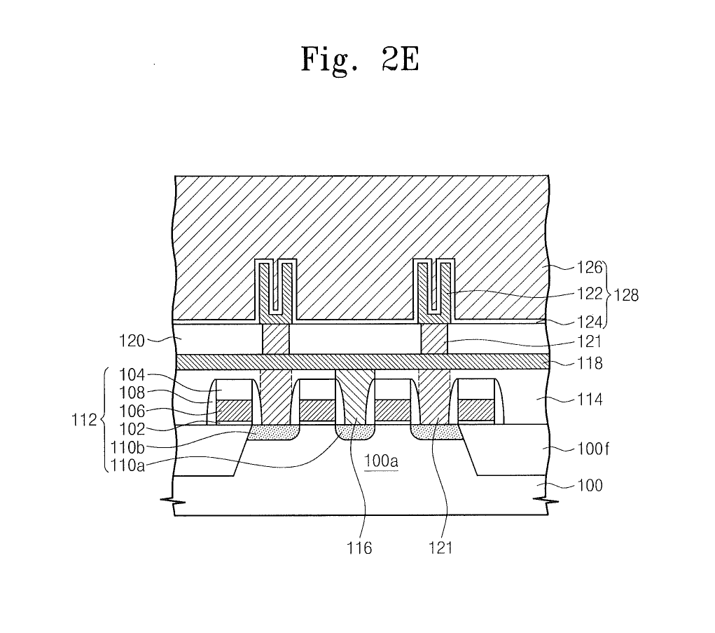

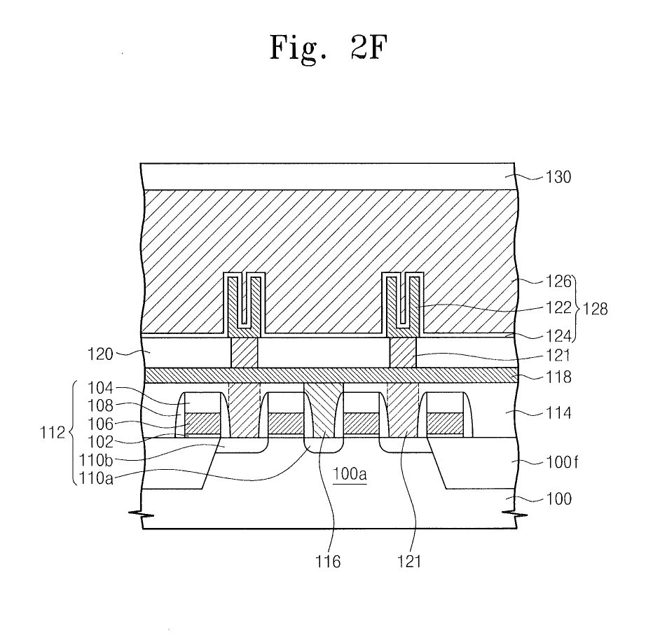

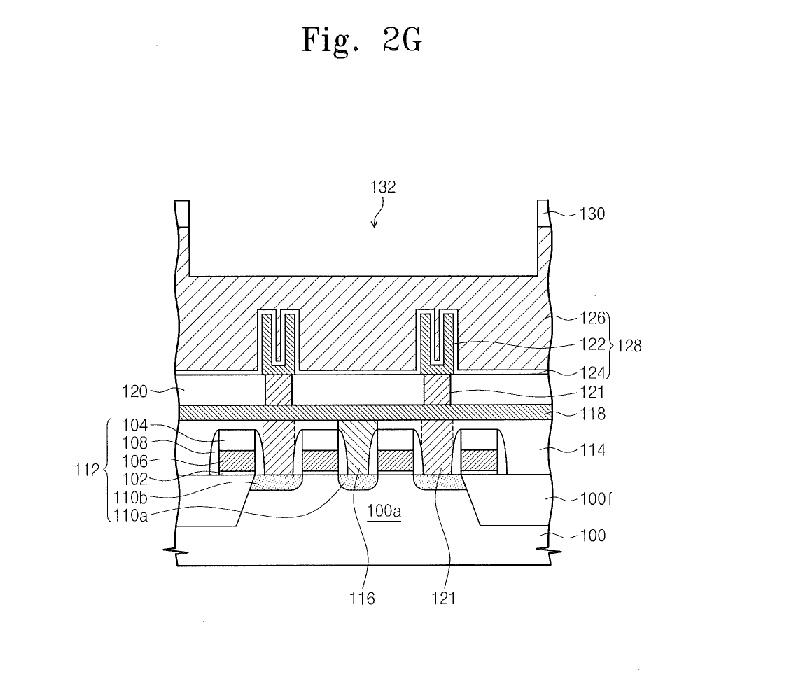

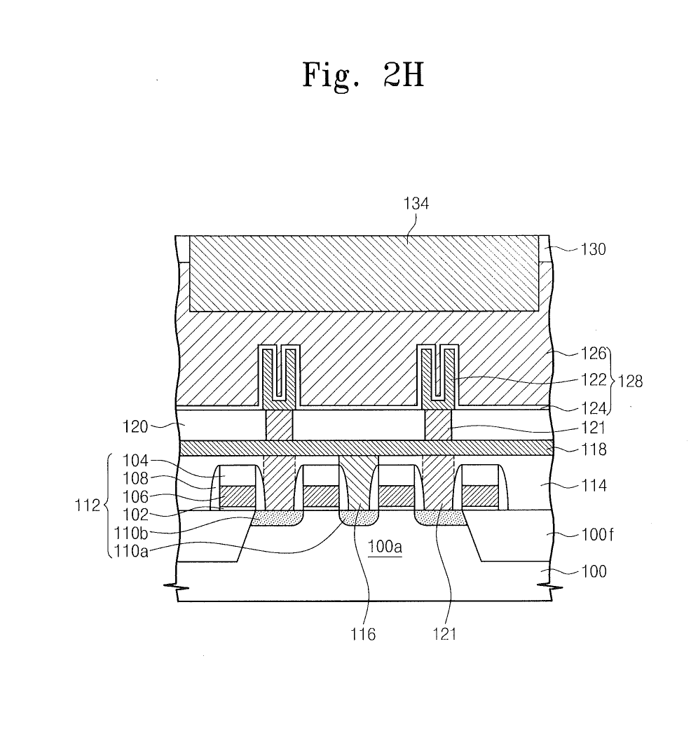

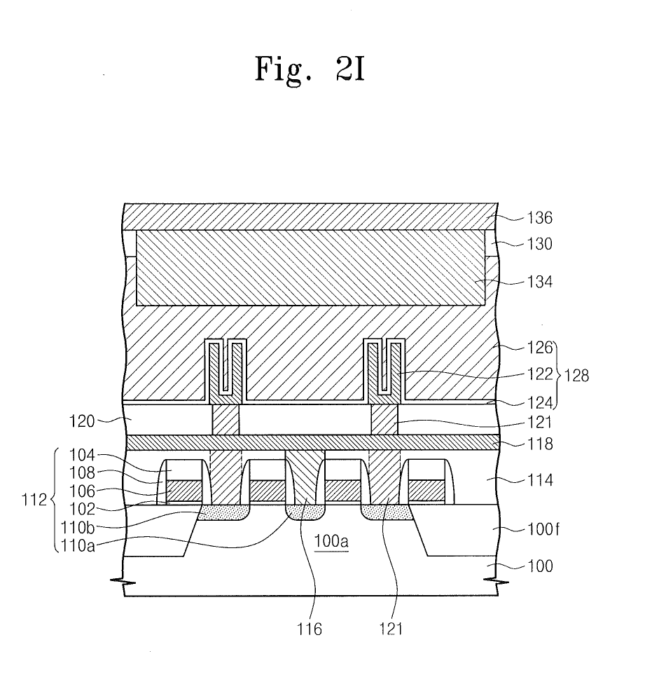

FIGS. 2A through 2I are cross sectional views illustrating a method of manufacturing the semiconductor device illustrated in FIG. 1. FIGS. 3A through 3I are top plan views illustrating a method of manufacturing the semiconductor device illustrated in FIG. 1.

Referring to FIGS. 2A and 3A, transistors 112 may be formed in a substrate 100 in which active regions 100a and field region 100f are formed.

The field region 100f may be formed in the substrate 100 using a shallow trench isolation (STI) process. The field region 100f may define the active regions 100a. Each of the active regions 100a may have an oval shape having a major axis direction along a first direction.

A gate insulating layer 102 and a first conductive layer (not illustrated) may be sequentially formed on the substrate 100. The gate insulating layer 102 may be formed by a thermal oxidation process or a chemical vapor deposition (CVD) process. The first conductive layer may include silicon doped with an impurity, metal or metal compound.

A first mask 104 is formed on the first conductive layer and gate electrodes 106 extending in a second direction may be formed using the first mask 104. The second direction is different from the first direction. For example, the second direction may be perpendicular to the first direction. The gate electrodes 106 may be spaced apart from one another at regular intervals and may be parallel to one another. The gate electrodes 106 may function as word lines.

An impurity is implanted into the substrate 100 exposed on both sides of each of the gate electrodes 106 to form a first impurity region 110a and a second impurity region 110b. The first and second impurity regions 110a and 110b may function as a source/drain region.

Spacers 108 may be formed on both sides of the gate electrode 106 and the first mask 104. The spacers 108 may include nitride. According to another embodiment, the first and second impurity regions 110a and 110b may be completed after the spacers 108 are formed.

As a result, the transistors 112 including the gate insulating layer 102, the gate electrode 106, the first mask 104, the first impurity region 110a, the second impurity region 110b and the spacers 108 respectively may be formed on the substrate 100.

Referring to FIGS. 2B and 3B, a first insulating layer 114 filling the transistors 112 may be formed on the substrate 100. First contact patterns 116 penetrating the first insulating layer 114 to be electrically connected to the first impurity regions 110a respectively may be formed.

According to some embodiments of the inventive concept, each of the first contact patterns 116 may have an oval shape having a major axis direction along a third direction. The third direction may obliquely cross a space between the first and second directions. Each of the first contact patterns 116 is disposed in the third direction.

Referring to FIGS. 2C and 3C, second conductive patterns 118 electrically connected to the first contact patterns 116 and extending in the first direction may be formed.

Elements of the second conductive patterns 118 may be spaced apart from one another and may be parallel to one another. The elements in the first contact patterns 116 may be electrically connected to each of the second conductive patterns 118. Each of the second conductive patterns 118 may also function as a bit line.

Referring to FIGS. 2D and 3D, a second insulating layer 120 filling the second conductive patterns 118 may be formed. Second contact patterns 121 penetrating the second insulating layer 120 to be electrically connected to the second impurity regions 110b respectively may be formed.

Referring to FIGS. 2E and 3E, capacitors 128 electrically connected to the second contact patterns 121 respectively may be formed. The capacitors 128 may include lower electrodes 122, a dielectric layer 124 and an upper electrode 126.

According to embodiments of the inventive concept, the lower electrodes 122 may have a hollow cylindrical shape a bottom surface of which is closed. For example, the lower electrodes 122 may be arranged in the first direction (row direction). Also, the lower electrodes 122 arranged in the first direction may be arranged in the second direction (column direction). The lower electrodes 122 arranged in the second direction may be disposed in a zigzag pattern.

The upper electrode 126 may have a flat upper surface and may have an upper surface that is the same level overall.

A process of forming the capacitors 128 according to an embodiment of the inventive concept may be described as follows.

A first sacrificial layer including openings exposing upper portions of the second contact patterns 121 may be formed on the second contact patterns 121 and the second insulating layer 120. A third conductive layer may be continuously formed along a surface profile of the first sacrificial layer. The third conductive layer may be formed not to fill the opening. Subsequently, a second sacrificial layer (not illustrated) filling the opening on which the third conductive layer is formed may be formed. The lower electrodes 122 nodes of which are separated from one another may be formed by etching upper portions of the second sacrificial layer and the third conductive layer so that a top surface of the first sacrificial layer is exposed. The inside and the outside of the lower electrode 122 may be exposed by removing the first and second sacrificial layers. The dielectric layer 124 may be conformally formed along a surface profile of the exposed lower electrodes 122. The dielectric layer 124 may be formed not to fill the inside of the lower electrode 122. The dielectric layer 124 may have a structure including an oxide layer, a nitride layer and an oxide layer. The upper electrode 126 filling the lower electrodes 122 and the dielectric layer 124 may be formed.

Referring to FIGS. 2F and 3F, a third insulating layer 130 may be formed on the capacitors 128. The third insulating layer 130 may perform a function of insulating the upper electrode 126 from a wire 136 being formed in a subsequent process.

Referring to FIGS. 2G and 3G, the third insulating layer 130 and the upper electrode 126 may be partly etched to form a recess 132 extending in the first direction.

The recess 132 may be formed around the third insulating layer 130 and the upper electrode 126. The recess 132 may be formed using an anisotropic etching process such as a plasma process. Because of the nature of the anisotropic etching process, the recess 132 may have a gradually narrowing width as it approaches the bottom.

Referring to FIGS. 2H and 3H, a third contact pattern 134 filling the recess 132 may be formed. According to embodiment of the inventive concept, the third contact pattern 134 may extend in the first direction.

In the case that the upper electrode 126 has a major axis direction along the first direction, an extension length of each of the third contact patterns 134 may be equal to or less than a length of major axis of the upper electrode 126. Each of the contact patterns 134 may have a substantially narrowing width as it approaches the bottom.

The third contact pattern 134 may electrically connect the upper electrode 126 and the wire 136 being formed in a subsequent process. A top surface of the third contact pattern 134 may have the substantially same level as a top surface of the third insulating layer 130.

Since the third contact pattern 134 has a line structure extending in a direction, a contact resistance between the third contact pattern 134 and the upper electrode 126 may be reduced.

Referring to FIGS. 2I and 3I, a fourth conductive pattern 136 electrically connected to the third contact pattern 134 may be formed on the third insulating layer 130. The fourth conductive pattern 136 may extend in the same direction as the extension direction of the third contact pattern 134. For example, elements in the fourth conductive patterns 136 may be spaced apart from one another at regular intervals and may be parallel to one another. According to the present embodiment, the fourth conductive pattern 136 may function as the wire 136.

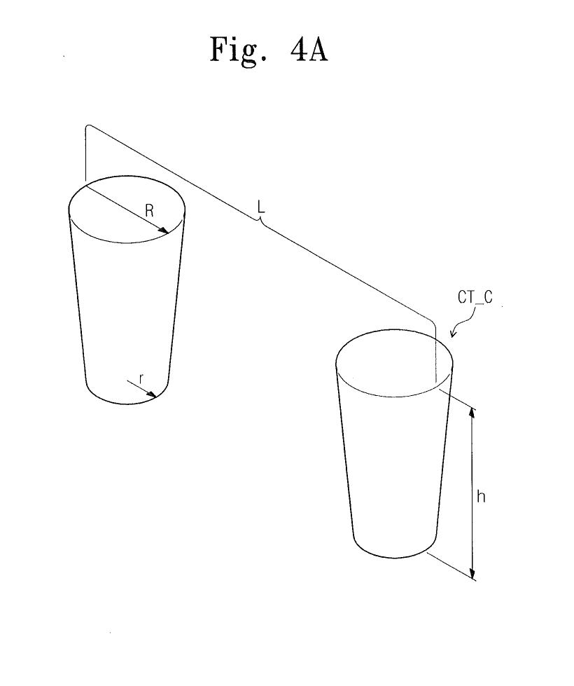

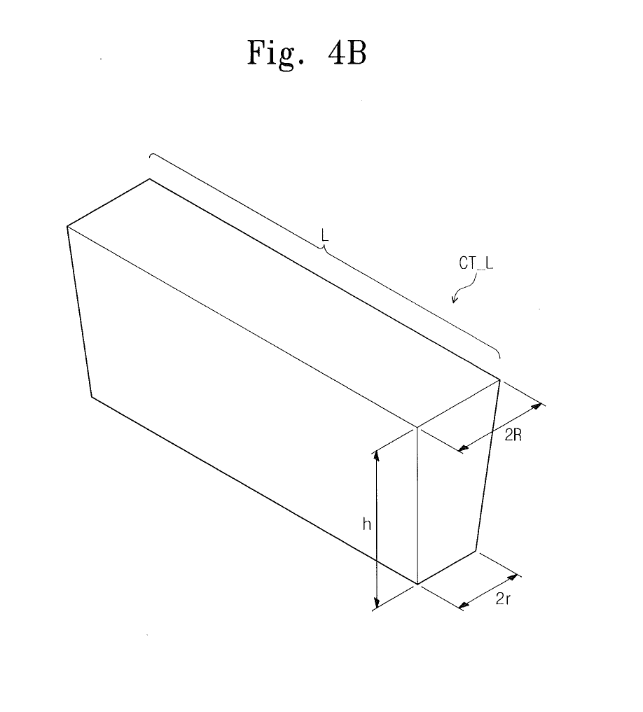

FIGS. 4A and 4B are schematic views for explaining differences in of electrical resistance between a cylindrical shape contact pattern and a line shape contact pattern in accordance with embodiments of the inventive concept.

Referring to FIGS. 4A and 4B, an area that contact patterns disposed on a distance L are in contact with an upper electrode is calculated.

Referring to FIG. 4A, two pillar shape contact patterns CT_C are disposed on a distance L and each of the pillar shape contact patterns CT_C has a gradually narrowing width as it approaches the bottom. An upper portion of the pillar shape contact pattern CT_C has a radius of R and a lower portion of the pillar shape contact pattern CT_C has a radius of r. A height of the pillar shape contact pattern CT_C is h. On the distance L, an area that the pillar shape contact pattern CT_C is in contact with the upper electrode is 2π2+2π(R+r)h.

Referring to FIG. 4B, one line shape contact pattern CT_L in accordance with embodiment of the inventive concept is disposed on the distance L and the line shape contact pattern CT_L also has a gradually narrowing width as it approaches the bottom. An upper portion of the line shape contact pattern CT_L has a width of 2R and a lower portion of the line shape contact pattern CT_L has a width of 2r. A height of the line shape contact pattern CT_L is h. On the distance L, an area that the line shape contact pattern CT_L is in contact with the upper electrode is 2(R+r)h+2rh+2Lh.

In the case that R is 44 nm, r is 3 nm, h is 100 nm and L is 516 nm, an area that the pillar shape contact pattern CT_C is in contact with the upper electrode is 53,162 nm2 and an area that the line shape contact pattern CT_L is in contact with the upper electrode is 150,192 nm2. The area that the line shape contact pattern CT_L is in contact with the upper electrode is about 2.8 times as large as the area that the pillar shape contact pattern CT_C is in contact with the upper electrode. When viewed from a viewpoint of a resistance, the line shape contact pattern CT_L may have a resistance reduced by about 65% as compared with a resistance of the pillar shape contact pattern CT_C.

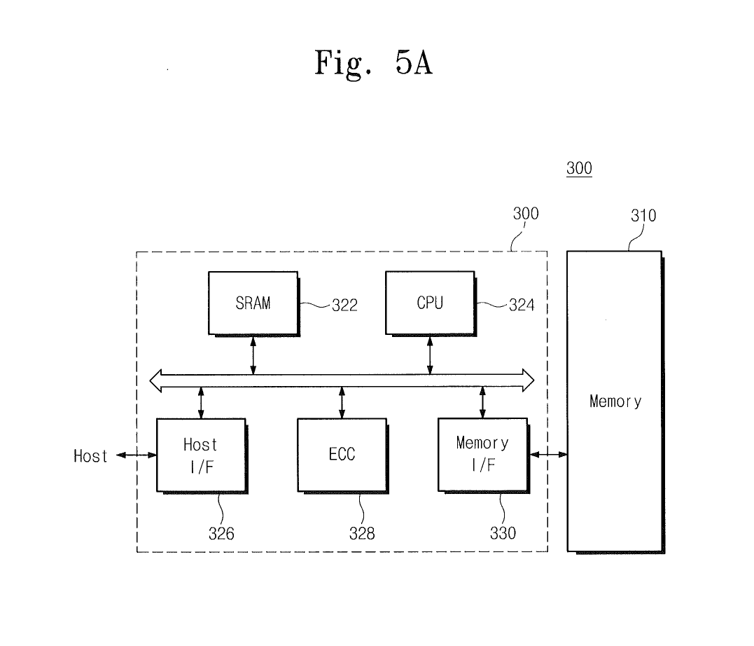

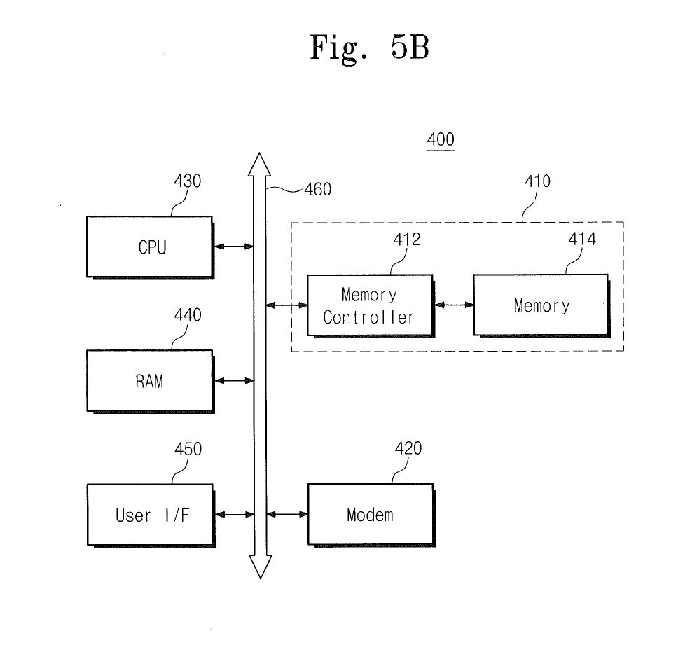

FIG. 5A is a block diagram illustrating a system including a memory device in accordance with embodiments of the inventive concept.

Referring to FIG. 5A, a memory device including a line shape contact pattern in accordance with embodiment of the inventive concept may be applied to a memory card 300. The memory card 300 may include a memory controller 320 controlling all the data exchanges between a host and a memory 310. A SRAM 322 may be used as an operation memory of a central processing unit (CPU) 324. A host interface 326 may include a data exchange protocol of the host connected to the memory card 300. An error correction code 328 may detect and correct an error included data readout from the memory 310. A memory interface 330 interfaces with the memory 310. The central processing unit 324 performs all the operations for a data exchange of the memory controller 320.

Since the memory 310 applied to the memory card 300 includes a line shape contact pattern in accordance with embodiment of the inventive concept, an area that the contact pattern is in contact with the upper contact increases and thereby a resistance of the contact pattern that is in contact with the upper electrode may be reduced. Also, a noise entering the upper electrode may be reduced.

FIG. 5B is a block diagram illustrating an information processing system to which a memory device in accordance with embodiments of the inventive concept is applied.

Referring to FIG. 5B, an information processing system 400 may include a semiconductor memory device in accordance with embodiment of the inventive concept, for example, a memory system 410 including a resistance variable memory. The information processing system 400 may include a mobile device or a computer. As an illustration, the information processing system 400 may include the memory system 410, and a modem 420, a central processing unit 430, a RAM 440 and a user interface 450 that are electrically connected to a system bus 460. The memory system 410 may store data processed by the central processing unit 430 or data received from the outside. The memory system 410 may include a memory 412 and a memory controller 414 and may be constituted to be the same with the memory card 300 described with reference to FIG. 5A. The information system 400 may be provided to a memory card, a solid state disk (SSD), a camera image sensor and an application chipset. As an illustration, the memory system 410 may be constituted by a solid state disk (SSD).

According to embodiments of the inventive concept, a contact pattern electrically connecting an upper electrode and a wire has a line shape. Thus, an area of the contact pattern that is in contact with the upper electrode may increase and a resistance of the contact pattern that is in contact with the upper electrode may be reduced.

The foregoing is illustrative of the inventive concept and is not to be construed as limiting thereof. Although a few embodiments of the inventive concept have been described, those skilled in the art will readily appreciate that many modifications are possible in the embodiments without materially departing from the novel teachings and advantages of the present invention. Accordingly, all such modifications are intended to be included within the scope of the present invention as defined in the claims. The present invention is defined by the following claims, with equivalents of the claims to be included therein.

1. A semiconductor device comprising:
a plurality of capacitors each including a lower electrode, an upper electrode on the lower electrode, and a dielectric layer between the upper and lower electrodes;
a contact pattern having a line shape extending in a direction, electrically connected to the upper electrodes; and
a wire electrically connected to the contact pattern.

2. The semiconductor device of claim 1, wherein a major axis direction of the upper electrode is the direction and the contact pattern has an extension length equal to or less than a length of the major axis of the upper electrode.

3. The semiconductor device of claim 1, wherein a width of the contact pattern becomes progressively less toward a bottom of the contact pattern.

4. The semiconductor device of claim 1, wherein the lower electrodes are spaced apart from one another along the direction.

5. The semiconductor device of claim 1, wherein the upper electrodes in the capacitors comprise flat upper surfaces that are about equal to one another in height.

6. The semiconductor device of claim 1, wherein the wire extends in the direction and has an extension length greater than an extension length of the contact pattern.

7. A semiconductor device comprising:
a substrate including an active region having a major axis in a first direction;
a plurality of transistors on the substrate, each including conductive patterns extending in a second direction perpendicular to the first direction, and first and second impurity regions on opposing sides of each of the conductive patterns;
bit lines electrically connected to the first impurity regions and extending in the first direction;
a plurality of capacitors electrically connected to respective ones of the second impurity regions;
a contact pattern having a line shape electrically connected to the plurality of capacitors and extending in the first direction; and
a wire electrically connected to the contact pattern and extending in the first direction.

8. The semiconductor device of claim 7, wherein each of the plurality of capacitors includes:
a lower electrode electrically connected to the second impurity region;
an upper electrode on the lower electrodes; and
a dielectric layer between the lower and lower electrodes, wherein the lower electrodes are spaced apart from one another in the first direction.

9-15. (canceled)

16. A Dynamic Random Access Memory (DRAM) device comprising:
a plurality of capacitors arranged in a line in a first direction, each including an upper electrode;
a contact pattern having a line shape that extends in the first direction and is electrically connected to each of the upper electrodes; and
a conductor on the contact pattern opposite the upper electrodes and electrically connected to the contact pattern.

17. The device according to claim 16 wherein the contact pattern comprises a unitary structure bridging at least two of the upper electrodes in the first direction.

18. The device according to claim 16 wherein a width of the contact pattern becomes progressively less toward the upper electrodes.

19. The device according to claim 16 further comprising:
a plurality of transistors on a substrate, each including conductive patterns extending in a second direction perpendicular to the first direction, and first and second impurity regions on opposing sides of each of the conductive patterns; and
bit lines electrically connected to the first impurity regions and extending in the first direction.

20. The device according to claim 16 wherein the upper electrodes each include flat upper surfaces facing the contact pattern, the flat upper surfaces each having respective heights that are about equal to one another.
